(19) United States
(12) Patent Application Publication
(10) Pub. No.: US 2025/0317043 A1
(43) Pub. Date: Oct. 9, 2025

(54) FREQUENCY CORRECTION CIRCUIT FOR SWITCHING CONVERTERS, CORRESPONDING CONVERTER DEVICE AND METHOD

(71) Applicant: STMicroelectronics International N.V., Geneva (CH)

(72) Inventors: Alessandro BERTOLINI, Vermiglio (IT); Stefano RAMORINI, Milano (IT); Alessandro GASPARINI, Cusano Milanino (IT)

(73) Assignee: STMicroelectronics International N.V., Geneva (CH)

(21) Appl. No.: 19/172,914

(22) Filed: Apr. 8, 2025

(30) Foreign Application Priority Data
Apr. 8, 2024 (IT) 102024000007738

(51) Int. Cl. H02M 1/00; H03K 7/06

(52) U.S. Cl. CPC H02M 1/0019; H02M 1/0025; H03K 7/06

(57) ABSTRACT

A correction circuit for a switching converter counters undesired reduction of switching frequency in response to a decrease in a load current at a converter output node. Detection circuitry receives a reference clock signal indicative of a lower bound for the switching frequency of the converter and a pulsed drive signal indicative of the switching frequency of the converter. In response to the switching frequency of the converter falling below said lower bound for the switching frequency of the converter, the detection circuitry produces an error signal. Current sink circuitry coupled to the output node of the converter sinks from the output node of the converter corrective current in response to receipt of the error signal from the detection circuitry.

### PRIORITY CLAIM

This application claims the priority benefit of Italian Application for Patent No. 102024000007738 filed on Apr. 8, 2024, the content of which is hereby incorporated by reference in its entirety to the maximum extent allowable by law.

### TECHNICAL FIELD

The description relates to switching converters.

Aspects of the present description can be used, for instance, in direct-current to direct-current (DC-DC) switching converters.

### BACKGROUND

Switching converters such as DC-DC converters are used in many applications to generate appropriate supply rails in order to facilitate operation of complex systems and performance as desired.

Such systems place an emphasis on both efficiency and performance and in various applications the converter is tailored to satisfy customer application scenarios. Improved efficiency and performance usually involve different modes of operation and the capability of maintaining high performance in many different scenarios is a desirable feature.

For instance, efficiency and performance for heavy loads is improved by operating the converter in continuous-conduction-mode (CCM) pulse width modulation (PWM) based operation at a switching frequency F_{SW}. Conversely, at light loads energy consumption is desired to be drastically reduced and the converter is operated in discontinuous-conduction-mode (DCM) and pulse frequency modulation (PFM), which is also referred to as “single-pulse-operation”. Switching activity is reduced in a sort of controlled way during PFM operation, leading to an increased low load efficiency (that is, quiescent current reduction).

In this mode of operation, the converter frequency is modulated according to the output load requirements (essentially, the load current) that is, the lower the load, the lower the switching activity. In this “non-PWM” mode of operation, the output is regulated by changing the switching frequency, instead of modulating the duty-cycle.

Desired compliance in different scenarios/applications with specifications in terms of electro-magnetic interference (EMI) noise and cross-talk within densely packed systems, results in limits being imposed on the DC-DC operating frequency imposed in terms of lower-bound values for the switching activity in CCM as well as in low-power-mode (i.e., DCM and PFM). A case in point is represented by consumer AMOLED display applications for smartphones, tablets and smartwatches, where the converter operating frequency may be actively monitored with corrective action put in place in order to counter undesired converter operation below a frequency threshold F_{MIN}.

Such frequency threshold is desired to be selectable on-the-fly in a range from 1 kHz to about 100s kHz.

This does not represent a problem in CCM operation, in so far as the switching frequency F_{SW} is well above F_{MIN} (1.5 MHz, for instance).

Conversely, when DCM is enabled and the converter performs in a PFM mode (in the presence of a light load, for instance), DCM/PFM operation may lead to conditions where the switching activity of the converter (essentially, the switching frequency F_{SW}) is reduced towards a lower bound for F_{MIN}, and converter operation is desired to be maintained without adversely affecting performances.

For instance, it is desired that: light-load efficiency/quiescent consumption should not degrade, and the converter should maintain PFM regulation within the specified lower-bound frequency without moving into fixed frequency CCM (PWM-operation); output ripple should not exceed an upper specified limit; CCM performance should not be affected in so far as stability, efficiency, current capability, and so on are concerned; and the converter should maintain the regulation capability with an operating frequency above certain limits, while meeting performance specifications.

This should desirably be the case irrespective of possible variations due to factors such as operation conditions and parameters (for instance input and output voltages V_{IN}, V_{OUT}, load, inductance L, capacitance C, value of the switching frequency F_{SW}, parasites, and so on), process-voltage-temperature (PVT) variations and other factors coming into play after final testing, packaging and assembly (aging, soldering, and so on).

United States Patent Application Publication No. 2015/0326123 A1, incorporated by reference, discloses a control circuit of a DC/DC converter wherein the control circuit includes a pulse modulator generating a comparison pulse. This is transitioned to an on level when a feedback voltage depending on an output voltage of the converter is lowered to a threshold voltage and then transitioned to an off level. A peak current detector asserts a detection signal when a coil current of the converter reaches a predetermined peak current. A logic part generates a control pulse which is transitioned to an on level when the comparison pulse is transitioned to the on level, and is transitioned to an off level at a time which is later among the time when the comparison pulse is transitioned to the off level and the time when the peak current detection signal is asserted. A driver switches a switching transistor of the converter based on the control pulse.

United States Patent Application Publication No. 2020/0136494 A1, incorporated by reference, discloses a DC-DC converter having an output node and at least one electronic switch. The DC-DC converter also includes: a first feedback loop configured to control a voltage at the output node by adjusting a first switching parameter of the at least one electronic switch; and a second feedback loop configured to adjust a second switching parameter of the at least one electronic switch. The second feedback loop includes a switched-capacitor circuit configured to determine a threshold signal based on an error between a reference signal and a control signal for the at least one electronic switch. The second feedback loop is configured to adjust the second switching parameter based on a comparison of an on-time signal with the threshold signal.

The article by S. Saggini, et al.: “Mixed-Signal Voltage-Mode Control for DC-DC Converters With Inherent Analog Derivative Action,” IEEE Transactions on Power Electronics, vol. 23, no. 3, pp. 1485-1493 May 2008, incorporated by reference, discloses a mixed-signal fixed frequency digital voltage-mode controller for DC-DC converters. Switch turn-on is determined by a system clock, while switch turn-off is determined asynchronously by comparing a signal proportional to the derivative of the output voltage and the voltage ramp driven by the digital-to-analog converter (DAC). The derivative action of the proportional-integral-derivative (PID) voltage-mode controller is inherently obtained by a combination of the analog front-end and the hard-wired digital logic, without requiring numerical computation of the derivative action nor analog reactive elements (capacitors).

The article by Miro Milanovic, et al.: “Implementation of voltage-to-frequency converter in digital based control for step-down DC-DC converter” DS2c.12-1.10.1109/EPEPEMC.2012.6397295, incorporated by reference, discloses measurement units based on voltage-to-frequency conversion for voltage and current control in step-down DC-DC converter enabling the digitalization of both voltage and current control loops. Measurements are performed using voltage control oscillators (VCO) and counters, which represent digital integrators.

There is a need in the art to address the issues discussed in the foregoing.

### SUMMARY

One or more embodiments relate to a circuit.

One or more embodiments relate to a corresponding converter device, that is a switching converter equipped with a circuit as described herein.

One or more embodiments relate to a corresponding method.

Solutions as described herein: are compatible with full on-chip integration and do not involve any extra pad/ball features or additional off-chip component; have no impact on the design of the associated converter; are largely insensitive to mismatch/PVT variations as well as to operating conditions and components derating; are based on closed-loop arrangements, wherein the system is automatically self-adaptive; do not require trimming; and are capable of automatically managing on-the-fly/real-time variations of the specified minimum frequency limit: only a references clock is possibly changed, with no changes in system configuration and virtually no constraints on the possible choices for the frequency limit.

In an embodiment, a correction circuit is configured to be coupled to a switching converter operating at a switching frequency that decreases in response to a decrease in a load current at an output node of the converter. The correction circuit comprises: detection circuitry configured to have applied thereto a reference clock signal indicative of a lower bound for the switching frequency of the converter and a pulsed drive signal indicative of the switching frequency of the converter, the detection circuitry configured to produce an error signal in response to the switching frequency of the converter falling below said lower bound for the switching frequency of the converter; and current sink circuitry driven by the detection circuitry, the current sink circuitry configured to be coupled to the output node of the converter, to receive the error signal from the detection circuitry and to sink from the output node of the converter a corrective current in response to the switching frequency of the converter falling below said lower bound for the switching frequency of the converter.

In an embodiment, a converter device comprises: a switching converter configured to supply a load current to an electrical load coupled to an output node of the converter and to operate at a switching frequency that decreases in response to a decrease in said load current, and the correction circuit as describe above having the detection circuitry coupled to the converter to receive therefrom said pulsed drive signal and to sink from the output node of the converter said corrective current in response to the switching frequency of the converter falling below said lower bound for the switching frequency of the converter.

In an embodiment, a method comprises: supplying a load current to an electrical load coupled to an output node of a switching converter wherein the converter is operated at a switching frequency that decreases in response to a decrease in the load current supplied to the electrical load at said output node of the converter; producing, based on a reference clock signal indicative of a lower bound for the switching frequency of the converter and a pulsed drive signal indicative of the switching frequency of the converter, an error signal indicating that the switching frequency of the converter falls below said lower bound for the switching frequency of the converter; and sinking from the output node of the converter a corrective current in response to said error signal indicating that the switching frequency of the converter falls below said lower bound for the switching frequency of the converter.

### BRIEF DESCRIPTION OF THE DRAWINGS

One or more embodiments will now be described, by way of example only, with reference to the annexed figures, wherein:

FIG. 1 is a diagram exemplary of a circuit as described herein applied to a switching converter;

FIG. 2 is a diagram exemplary of another circuit as described herein applied to a switching converter;

FIG. 3 is a circuit diagram exemplary of possible details of the circuit of FIG. 2;

FIG. 4 is a diagram exemplary of a further circuit as described herein applied to a switching converter;

FIG. 5 is a circuit diagram exemplary of possible details of the circuit of FIG. 4;

FIG. 6 represents possible time behaviors (waveforms) of signals that may occur in the circuit of FIG. 4;

FIG. 7 is a circuit diagram of a possible variant of the circuit of FIG. 4;

FIG. 8 is a diagram exemplary of a possible mixed-signal implementation of a circuit as described herein applied to a switching converter;

FIG. 9 is a diagram exemplary of a further possible mixed-signal implementation of a circuit as described herein applied to a switching converter;

FIGS. 10, 11, and 12 are circuit diagrams exemplary of possible implementation details of the circuits of FIG. 8 and FIG. 9; and

FIGS. 13 and 14 are circuit diagrams exemplary of other possible implementation details of the circuits of FIG. 8 and FIG. 9.

### DETAILED DESCRIPTION

The figures are drawn to clearly illustrate the relevant aspects of the embodiments and are not necessarily drawn to scale.

The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

Once more, for the sake of simplicity and ease of explanation, a same designation may be applied throughout this description to designate: a certain node or line as well as a signal occurring at that node or line, and/or a certain component (such as a capacitor, resistor or inductor of coil) as well as electrical parameters thereof.

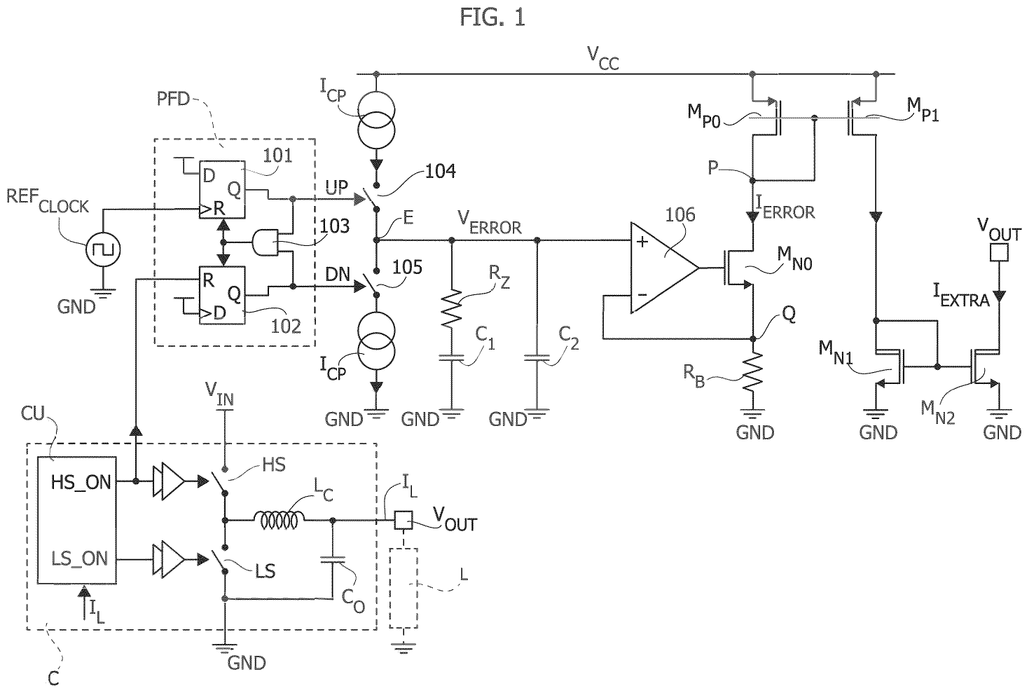

FIG. 1 is a circuit diagram of a solution as disclosed herein as applied to a DC-DC converter C configured to have coupled an electrical load L (of any known type) at an output node V_{OUT}.

In the figures, the load L is deliberately represented in dashed lines in so far as the load may in fact represent a distinct element from the embodiments intended to be coupled to the converter C only by the end user and/or when in use to supply the load L.

Converters such as DC-DC are extensively used in many applications in various areas. The automotive sector and consumer electronics are (non-limiting) examples of areas of possible application of such converters.

In FIG. 1, the converter C is illustrated in a simplified manner as a generic buck converter having a high-side switch HS and a low-side switch LS (electronic switches such as MOSFET transistors, for instance) arranged with the current flow lines therethrough cascaded in series in a current flow line between an input node at voltage V_{IN} and ground GND.

The high-side switch HS and the low-side switch LS are alternatively turned on and off via respective drivers having applied drive signals HS_ON and LS_ON from a control unit CU.

An inductor L_{C} is coupled to an intermediate node between the high-side switch HS and the low-side switch LS to generate across an output capacitor C_{O} an output signal to be applied to the load L at an output node of the converter (at a voltage V_{OUT}) so that the load is traversed by a load current I_{L}.

The control unit CU is sensitive to V_{OUT}, and since V_{OUT} is affected by I_{L}, the control unit CU is (at least indirectly) sensitive to I_{L}, that is to the current I_{L} through the load L and is configured to control switching operation of the converter C as desired via the signals HS_ON and LS_ON controlling the switches HS and LS.

The sensitivity of the control unit CU to the load current I_{L} drawn (sunk) from the node V_{OUT} plays a role in the solutions described herein and for that reason it is explicitly portrayed in the figures.

Structure and operation of a converter (buck-type, by way of non-limiting example) such as the converter C are otherwise known to those of skill in the art and a detailed description is not provided here for brevity.

For the purposes of the present description, the converter C can be regarded essentially as a “black-box” in so far as the description is primarily concerned with a correction circuit configured to be coupled to a switching converter such as the converter C. The converter C is configured to operate at a switching frequency F_{SW} and the correction circuit is intended to counter conditions where (as discussed previously) the switching frequency F_{SW} of the converter C may undesirably decrease below a lower frequency F_{MIN} in response to a decrease in the load L, namely a reduction in the current I_{L} absorbed by an electrical load L coupled to the output node V_{OUT} of the converter C.

A DC-DC buck topology is illustrated here merely by way of non-limiting example of converters wherein switching activity is continuously monitored (observing one of the driver signals HS_ON or LS_ON of the converter C, for instance) and compared with a time reference such as a clock signal REF_{CLOCK} that corresponds to (or at least indirectly conveys information on) a lowest desirable value F_{MIN} for the switching frequency F_{SW} of the converter C.

That is, F_{MIN} represents a lower bound under which it is desired that the switching frequency should not drop for the reasons discussed in the introductory portion of the description: the solutions described herein are thus intended to counter the undesired reduction of the operating (switching) frequency of a switching converter below a lower bound F_{MIN} that may occur in response to a reduction of the load (current).

In response to a comparison outcome indicating that the DC-DC converter C is prone to switch below the specified limit, a variable extra current is sunk from the regulated output voltage V_{OUT}, thus performing a corrective action implemented as a modulated (increased) dummy load applied to the node V_{OUT}.

The solutions described herein thus deal with a correction circuit configured to be coupled to a switching converter operating at a switching frequency that decreases in response to a decrease in a load current at an output node of the converter.

As noted, the correction circuit is intended to counter undesired reduction of the operating (switching) frequency of the switching converter below a lower bound that may occur in response to a reduction of the load (current).

To that effect, the solutions described herein include detection circuitry with current sink circuitry cascaded thereto.

The detection circuitry is configured to have applied thereto: a reference clock signal indicative of a lower bound for the switching frequency of the converter, and a pulsed drive signal indicative of the switching frequency of the converter.

The detection circuitry is configured to produce an error signal in response to the switching frequency of the converter falling below the lower bound set for the switching frequency of the converter (which may be possibly varied on-the-fly).

The current sink circuitry is driven by the detection circuitry and is configured to: be coupled to the output node of the converter, receive the error signal from the detection circuitry, and sink from the output node of the converter a corrective current in response to the switching frequency of the converter falling below the lower bound set for the switching frequency of the converter.

In FIG. 1, a phase-frequency-detector PFD is shown including two flip-flops 101, 102 and an AND gate 103.

A reference clock signal REF_{CLOCK} indicating a lowest switching frequency F_{MIN} is used to clock the first flip-flop 101 whose D input is coupled to a supply rail or node (the supply node or rail at a voltage V_{CC} referred to in the following, for instance) like the D input of the second flip-flop 102.

The Q outputs from the two flip-flops 101, 102 are applied to the inputs of the AND gate 103 whose output is applied to the reset inputs R of the two flip-flops 101, 102.

The second flip-flop 102 is clocked via an “on” signal (the high-side “on” signal HS_ON, for instance) of one of the drivers in the converter C.

The Q outputs from the flip-flops 101, 102 are applied as “up” and “down” signals UP and DN to turn on (make conductive) two switches 104, 105 arranged with the current flow paths therethrough between the supply voltage “rail” at a voltage V_{CC} and ground GND.

For instance, the switches 104, 105 (intended to be traversed by a current I_{CP} when conductive) can be implemented as electronic switches such as MOSFET transistors, for instance, receiving the signals UP and DN at their control terminals (gates) and having the source-drain current flow paths therethrough cascaded in series in the current flow line between the supply rail V_{CC} and ground GND.

An error signal V_{ERROR} at a node E intermediate the switches 104, 105 is applied to one input (non-inverting, for instance) of a differential amplifier 106 and also to filter circuitry coupled between the node E and ground GND.

In the exemplary case illustrated herein, such filter circuitry includes the parallel connection of: a (first) capacitor C₁ with a series resistor R_{Z}; and a (second) capacitor C₂.

The output from the amplifier 106 drives the control terminal (gate) of a MOSFET transistor M_{N0} having the source-drain current flow path therethrough (intended to be traversed by a current I_{ERROR}) arranged between a node P and a node Q in a further current flow line between the rail V_{CC} and ground GND, wherein: a diode-connected MOSFET transistor M_{P0} is arranged with the source-drain current flow path therethrough between the rail V_{CC} and the node P, and a resistor RB is arranged between the ground and the node Q, which is also coupled to the other input (inverting, for instance) of the differential amplifier 106.

Advantageously, the MOSFET transistor M_{N0} is n-channel if transistor M_{P0} is p-channel.

The diode-connected MOSFET transistor M_{P0} is gate-to-gate coupled in a current mirror arrangement with a further MOSFET transistor M_{P1} having a source-drain current flow path therethrough arranged in a still further current flow line between the rail V_{CC} and ground GND including a diode-connected MOSFET transistor M_{N1} having the source-drain current flow path therethrough in series with the source-drain current flow path through the MOSFET transistor M_{P1}.

The diode-connected MOSFET transistor M_{N1} is gate-to-gate coupled in a current mirror arrangement with an output MOSFET transistor M_{N2} having a source-drain current flow path therethrough intended to be traversed by a current I_{EXTRA} between the output node V_{OUT} (of the converter C) and ground GND, the current I_{EXTRA} being thus sunk from the node V_{OUT} thus providing an extra “dummy” load adding to the load L.

The circuit illustrated in FIG. 1 essentially implements a phase-frequency detector (PFD) wherein one of the driving signals of the converter (the signal HS_ON, for instance) is compared in a phase-domain with a clock reference signal REF_{CLOCK} to obtain information on a phase (and thus frequency) offset or error between the reference signal REF_{CLOCK}, which is indicative of the lowest frequency F_{MIN} desired for the switching activity of the converter C, and a signal such as HS_ON which is indicative of the actual, current switching activity (frequency) of the converter C.

The error can be represented by voltage signal V_{ERROR} (see the charge-pump arrangement including the elements 104, 105) and exploited to drive a variable current generator (the amplifier 106 and the current-mirror circuitry cascaded thereto) realizing an output dummy load, wherein a negative feedback loop aligns the switching activity (as represented by HS_ON) to the clock reference REF_{CLOCK}: same phase and therefore frequency.

Charge pump arrangements are known per se in the art, for instance comprising two matched current mirrors that are switched to provide net charge on an associated filter (see the elements C₁, R_{Z}, while—at least—C₂ is not compulsory).

Phase-frequency detector (PFD) arrangements are likewise known per se in the art, for instance as “digital” circuits fed with two inputs and providing two output values based on the timing relationship between the rising edges of the inputs.

For instance, in the case illustrated in FIG. 1, the output UP, DN can be such that: UP is set if a rising edge of REF_{CLOCK} occurs and reset when a rising edge of HS_ON occur; and, conversely DN is set if rising edge of HS_ON arrives before a rising edge of REF_{CLOCK} and a rising edge of REF_{CLOCK} resets DN.

It is noted that using an amplifier such as the differential amplifier 106 illustrated in FIG. 1 is not mandatory: in fact, a source follower stage can be enough to perform a voltage-to-current conversion of the error signal V_{ERROR} at the node E.

The output current mirrors illustrated in FIG. 1 facilitate magnifying the error current signal and also act as level shifters between different domains (if desired, for example from low-voltage to high-voltage rails).

It is otherwise noted (this applies to all the examples discussed throughout this description) that an adequate level is advantageous for the error current signal, but the exact relationship of the error current signal (and thus of the correction current I_{EXTRA} sunk from the output node V_{OUT} that adds to the load current I_{L}) to the difference revealed between the switching frequency of the converter (as possibly sensed via the signal HS_ON) and the reference frequency REF_{CLOCK} is not a dominant factor for the purposes herein in so far as corrective action is in any case implemented when the converter switching frequency is found to be lower than F_{MIN} as represented by REF_{CLOCK}.

The circuit illustrated in FIG. 1 is asymmetric, in so far as it is configured to sink an extra output current I_{EXTRA} form the converter output and can therefore (only) increase the DC-DC switching activity (frequency) if below the reference value represented by REF_{CLOCK}.

When the converter C is operating with a switching frequency F_{SW} higher than REF_{CLOCK}, a circuit as illustrated in FIG. 1 saturates, accumulating a negative phase error; in this case V_{ERROR} and I_{EXTRA} simply go to zero and no corrective action is implemented.

By way of example, a circuit as illustrated in FIG. 1 can be applied in a DC-DC converter C regulating an output voltage V_{OUT} of 3V.

Operation of a converter C in a PFM mode was simulated at about 164 kHz, with a frequency limiting feature enabled with a minimum frequency value F_{MIN} at F_{MIN}=200 KHz. A circuit as illustrated in FIG. 1 was thus found to increase the operating frequency of the converter in PFM mode precisely until the limit of 200 kHz is reached.

An on-the fly change of F_{MIN} to 300 kHz was then simulated at 1 ms and after a short transient the circuit reaches a new steady state with the converter operating at 300 kHz.

At 1.5 ms, a reduction of load current was simulated with the circuit found to correctly track such event restoring a new steady state. Finally, at 2 ms a load current increase was simulated to a value leading the converter to operate “naturally” well above 300 kHz.

At that point, the circuit of FIG. 1 simply saturates and no longer provides a corrective action (that is, no dummy-load current is added to the load current).

By way of reference, a slow load transient was simulated for the DC-DC converter of FIG. 1 with a slow load transient from no load up to 100 mA, with F_{MIN} set to 300 kHz and the frequency limiting feature both enabled and disabled.

In both instances the converter C was found to operate in a PFM mode, and: with the frequency limiting feature enabled, the PFM frequency was maintained at F_{MIN} finally saturating when the external load was substantial so that no corrective action was required (that is, with the external load leading the DC-DC converter C to operate above 300 kHz); and with the frequency limiting feature disabled, the DC-DC converter reached a minimum frequency of a couple of kHz, well below F_{MIN}.

A solution as illustrated in FIG. 1 facilitates avoiding that a DCM/PFM operated converter reduces its switching activity below a specific frequency range, no matter the operative condition, external components nor PVT variations.

Possible CCM operation and performance are not adversely affected: when in a CCM mode, the additional circuitry associated to the converter C remains in an idle state.

It is noted that a master clock reference in the MHz range is currently available in power management integrated circuits (PMICs) from which a clock signal REF_{CLOCK} can be easily derived.

A solution as illustrated in FIG. 1 leads to a precise phase alignment of REF_{CLOCK} and HS_ON (or any other signal exploited that carries information about the converter activity). This feature is advantageous in PMICs with multiple converters constrained to given low-frequency limits: if different phase versions of REF_{CLOCK} are used, cross-talk between converters is countered (thus facilitating time-interleaving).

A solution as illustrated in FIG. 1 has a reduced corrective action (extra output current sunk) to counter undesired operation of a DC-DC converter below a limit. The converter switching activity is maintained at that limit with a reduces impact on efficiency.

A solution as illustrated in FIG. 1 does not involve extra process masks or specific devices; furthermore, it does not pose any constrain on the DC-DC architecture or topology and can be applied to any converter operated in a PFM mode.

In fact: the converter C represents a sort of “black-box” for the monitoring circuit illustrated in FIG. 1, which facilitates flexibility/versatility by being essentially add-on/plug-in elements adapted to be deployed in any DC-DC converter; and only a signal carrying information about the DC-DC switching activity (for instance a power-stage driving signal such as the high-side signal HS_ON, but other signals such as any feedback signal to the control unit CU from the power-stage drivers can be used for that purpose) is exploited, with no constraints on the duty-cycle of that signal in so far as a PFD is sensitive only on a single edge (rising-edges, for instance).

In this latter respect, the solution as illustrated in FIG. 1 can be regarded as being PLL-based, that is based on a phase-locked-loop (PLL).

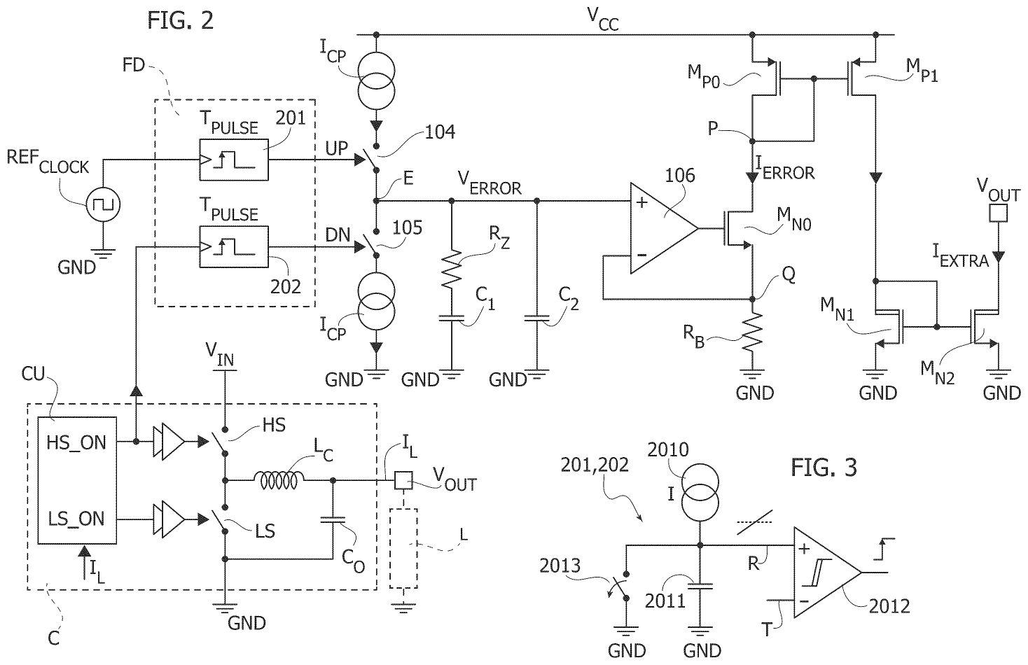

FIG. 2 illustrates another possible implementation of the same basic concept discussed in the foregoing which can be regarded as being FLL-based, that is based on an (analog) frequency-locked-loop (FLL).

For the sake of brevity, parts or elements like parts or elements already discussed in connection with FIG. 1 are indicated in FIG. 2 with the same reference symbols. Therefore, a detailed description of these parts or elements that were already discussed will not be repeated.

As in the case of FIG. 2, the underlying concept is again to continuously monitor the switching activity/frequency of the converter C (for instance, based on one of the driver signals such as HS_ON, but any other signal carrying the same information can be used for that purpose) and compare that switching signal with a time reference indicative of a minimum admissible switching frequency F_{MIN}: again, a clock signal such as the signal REF_{CLOCK} can be used for that purpose.

Based on such a comparison, if the DC-DC is found to (tend to) switch below the specified limit F_{MIN}, a (variable) extra current I_{EXTRA} is sunk from the regulated output V_{OUT}: also in the case of FIG. 2, the corrective action is performed via a modulated dummy load.

In the solution of FIG. 2, the comparison leading to the generation of signals UP and DN to control the switches 104 and 105 (and thus to the generation of the error signal V_{ERROR}) is performed in terms of frequency (in the solution of FIG. 1 this is done in terms of phase, by relying on the fact that a phase alignment implies a frequency alignment as well).

An analog FLL implementation based on a fixed-pulse frequency-detector (FP-FD) will be first discussed in connection with FIG. 2, with additional details discussed in connection with FIG. 3.

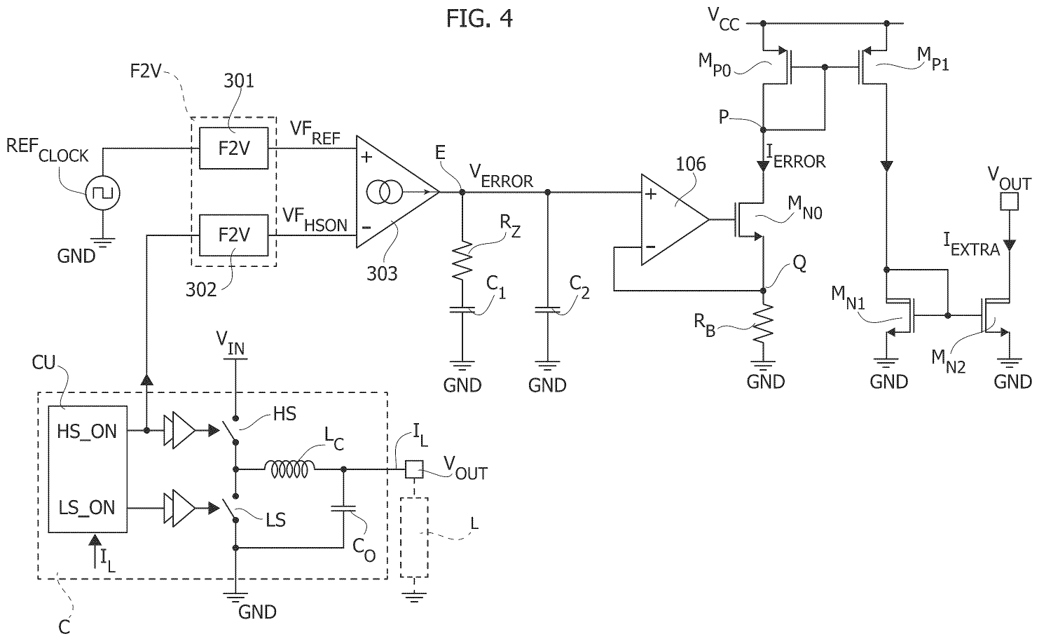

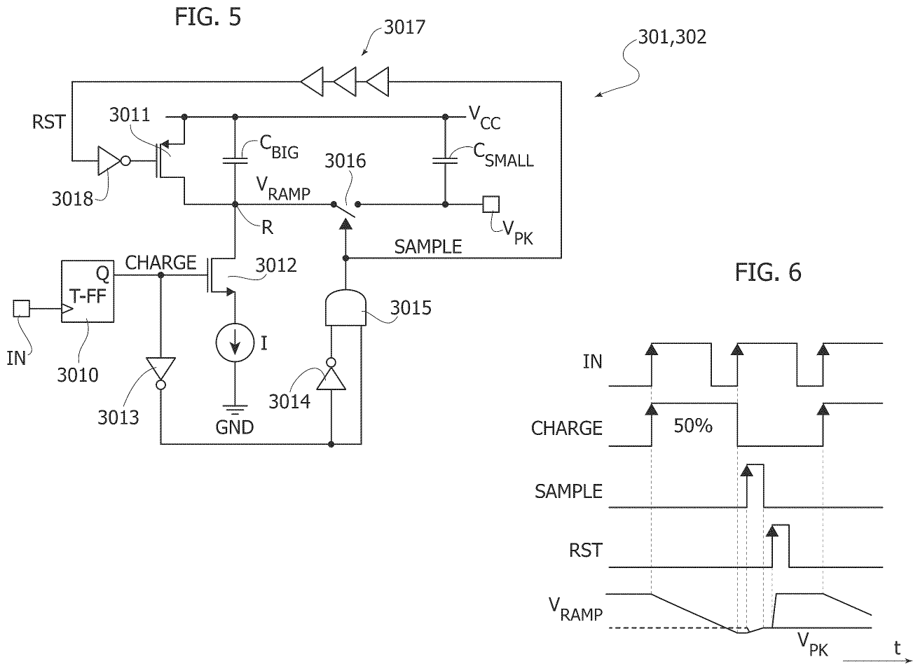

An alternative analog FLL implementation based on frequency-to-voltage (F2V) conversion will then be discussed in connection with FIG. 4, with additional details discussed in connection with FIG. 5 and FIG. 6.

In the analog FLL implementation based on a fixed-pulse frequency-detector (FP-FD) of FIG. 2 the signal HS_ON that represents the switching activity of the converter C (it is once more recalled that other signals carrying the same information can be used for that purpose) is compared by means of a frequency-detector FD with a clock reference signal REF_{CLOCK}.

As otherwise known to those of skill in the art, a frequency detector FD as illustrated in FIG. 2 can include two pulse generators 201, 202 configured to generate constant-width pulses of duration T_{PULSE} at each rising edge of the signals HS_ON and REF_{CLOCK}.

The pulses from the generators 201 and 202 can be used to control (directly) a charge pump arrangement 104, 105 as already discussed in connection with FIG. 1: the net charge moved on the associated output filter (here exemplified by the resistor R_{Z} and the capacitors C₁, C₂ at the input side of the amplifier 106) depends on the frequency difference between the signal HS_ON and the clock reference signal REF_{CLOCK}.

Using (matched) pulse generators, configured to generate notionally identical pulses eliminates the dependence on the duty cycle of the converter switching signal (HS_ON, for instance) and REF_{CLOCK}.

A (frequency) error information is therefore obtained and such error is converted into a voltage signal V_{ERROR} (via the charge-pump and filter arrangement already repeatedly discussed). The signal V_{ERROR} at the node E is used to drive a variable current generator (via the current mirror already discussed in connection with FIG. 1) realizing an output dummy load.

Again, a negative feedback loop aligns the switching activity (as exemplified by HS_ON) to the clock reference REF_{CLOCK} (to obtain a same frequency).

Also in the case of FIG. 2: the amplifier 106 is not compulsory, in so far as a source follower stage can be enough to perform a voltage-to-current conversion of the error signal V_{ERROR}; and the output current mirrors facilitate magnifying the error current signal and also act as level shifters between different domains (if desired, for example from low-voltage to high-voltage rails).

The system illustrated in FIG. 2 is again asymmetric, since it is configured to sink an extra output current I_{EXTRA} at the output node V_{OUT} and therefore can (only) increase the switching activity of the DC-DC converter if below the frequency of the reference signal REF_{CLOCK}.

Once more, when the converter is operating at an actual switching frequency F_{SW} higher than the frequency REF_{CLOCK}, the system illustrated in FIG. 2 saturates, accumulating a negative frequency error; in this case V_{ERROR} at the node E and I_{EXTRA} become zero and no (unnecessary) corrective action is implemented.

Depending on the value selected for the duration T_{PULSE} of the pulses, the pulse generator 201, 202 can be obtained in different ways known in the art.

As represented in FIG. 3, an advantageous option is represented by an analog timer comprising a current generator 2010 (of any known type for the purpose) sourcing a current I to a capacitor 2011 thus creating a ramp signal R that is compared with a reference T in a comparator 2012 (a hard-squarer comparator or inverter) and periodically reset to zero via a switch 2013.

A lower limit for the value selected for the duration T_{PULSE} of the pulses can be given by the charge-pump non-linearities and non-idealities, while an upper limit on the pulse duration is given by the maximum operating frequency.

It is otherwise noted that the resistor R_{Z} and the capacitor C₂ may be unnecessary: a type-I network may be enough, while the capacitor C₂ facilitates reducing the ripple on the signal V_{ERROR} and the resistor R_{Z} facilitates boosting the phase margin.

Behavior of a circuit as illustrated in FIG. 2 was simulated in the case of an inverting buck-boost DC-DC converter C regulating a voltage of −9V with the converter initially freely operating in PFM mode at no load. At 6 ms the frequency limit feature was enabled with F_{MIN} set to 400 kHz. The converter operating frequency was observed up to the desired limit. At 6.6 ms a new load condition was applied and a new steady state was reached maintaining switching operation of the DC-DC converter within the boundary of 400 kHz.

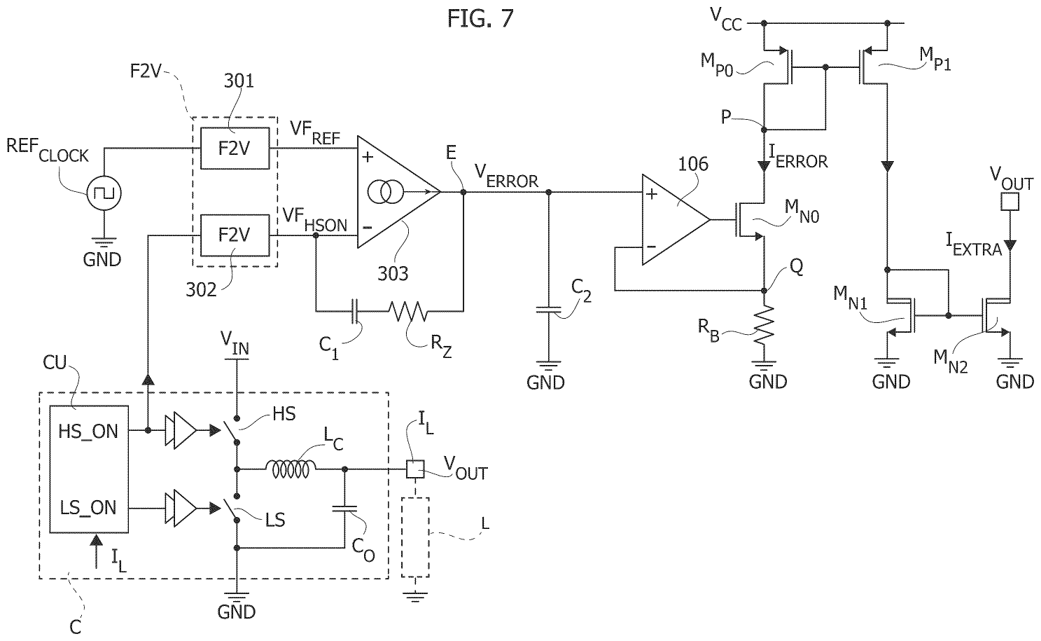

An alternative analog FLL implementation based on frequency-to-voltage (F2V) conversion will now be discussed in connection with FIG. 4. Additional details of such an implementation are discussed in connection with FIG. 5 and FIG. 6, with a possible variant implementation discussed in connection with FIG. 7.

Again, for the sake of brevity, parts or elements like parts or elements already discussed in connection with FIG. 1 and FIG. 2 are indicated in FIG. 4 and FIG. 7 with the same reference symbols. Therefore, a detailed description of these parts or elements that were already discussed will not be repeated.

A frequency-to-voltage converter F2V is used including two F2V conversion stages 301, 302 having applied thereto the reference clock signal REF_{CLOCK} and a “switching activity” signal from the converter C such as, again by way of example, the signal HS_ON. Once more, another signal such as a feedback signal carrying the same information (actual switching frequency of converter C) can be used for that purpose.

The output signals VF_{REF} and VF_{HSON} from the two F2V conversion stages 301, 302 are applied to the inputs (non-inverting and inverting) of a differential amplifier 303 in order to obtain at the output thereof a voltage signal V_{ERROR} at the node E conveying information about the frequency of the digital-like signal HS_ON (with reference to the frequency of the signal REF_{CLOCK}).

Circuits such as the circuits 301, 302 can be realized as depicted in FIG. 5.

As illustrated, a toggle flip-flop 3010 receives the input signal (either REF_{CLOCK} or HS_ON) at an input node IN and produces a signal CHARGE with a 50% duty-cycle starting from the input signal at the node IN (via frequency division) thus removing the dependency/constrain on the duty-cycle of the input signal. A sawtooth signal (V_{RAMP}) is obtained at a node R intermediate a first MOSFET transistor 3011 and a second MOSFET transistor 3012 arranged with the source-drain current paths therethrough cascaded in current flow line between a supply rail at a voltage V_{CC} and ground GND.

The Q output from the flip-flop 3010 is applied to the control terminal (gate) of the MOSFET transistor 3012 as well as to a logical inverter 3013 whose output is applied (directly and in a logically inverted form obtained via a further logical inverter 3014) to the inputs of an AND gate 3015.

The output from the AND gate 2015 provides a SAMPLE signal that: on the one hand, controls a switch 3016 (this may be again an electronic switch such as a MOSFET transistor) that couples the node R (signal V_{RAMP}) to an output node V_{PK} (VF_{REF} and VF_{HSON}, respectively, in the stages 301 and 302); and on the other hand, is applied via a chain of buffer stages 3017 to another logical inverter 3018 that drives the control terminal (gate) of the MOSFET transistor 3011.

A first “large” capacitor C_{BIG} is coupled between the voltage rail V_{CC} and the node R and a second “small” capacitor C_{SMALL} (“big” and “small” being in relative sense) is coupled between the voltage rail V_{CC} and the output node V_{PK}.

The capacitor C_{BIG} is charged with a constant current I and the peak voltage V_{PK} of the ramp signal V_{RAMP} is sampled via the switch 3016 and stored on the capacitor C_{SMALL} at intervals given by the input frequency REF_{CLOCK} and HS_ON, respectively, in the stages 301 and 302): a peak-detector circuit is obtained in response to C_{BIG} being selected (much) larger than C_{SMALL}.

The diagram of FIG. 6 illustrates, against a common abscissa time scale t, possible time behaviors (waveforms) of (from top to bottom): an input signal at the input node IN (either REF_{CLOCK} or HS_ON); the signal CHARGE at the output of the flip-flop 3010; the signal SAMPLE from the AND gate 3015; a reset signal RST applied in a manner known per se, not shown for simplicity, having a rising edge to periodically reset to V_{CC} the signal V_{RAMP}; and the signal V_{RAMP}.

Using two F2V converters 301, 302—one coupled to the reference signal REF_{CLOCK} and the other to HS_ON—two analog signals VF_{REF} and VF_{HSON} are then compared by means of the amplifier 303 acting as an error amplifier (EA).

The error voltage V_{ERROR} provided to the amplifier 106 is once more related to the frequency difference between REF_{CLOCK} and HS_ON and a negative frequency correction feedback loop is closed by means of a transconductor sinking from the output V_{OUT} a current I_{EXTRA} proportional to the error voltage.

The system once more aligns the switching activity as represented by HS_ON (this is by way of example: as repeatedly noted, any signal carrying information on the actual switching frequency of the converter C can be used) with the clock reference represented by REF_{CLOCK}.

In comparison with the solutions based on FP-FD comparison more degrees of freedom are available in the case of FIG. 4: in fact, the relationship between the “compensation” current I_{EXTRA} and the ripple on the signal V_{ERROR} at the node E can be relaxed (possibly limiting trade-offs are no longer involved) and improved performance is facilitated.

One may also note that, at least in principle, a full distinct F2V converter fed by the signal REF_{CLOCK} (reference 301 in FIG. 4) is not strictly mandatory and can be implemented as a “virtual” F2V converter, namely as a simple equivalent voltage reference indicative of the reference frequency REF_{CLOCK}.

Once more: the resistor R_{Z} and the capacitor C₂ are not mandatory (a type-I network may be enough, while the capacitor C₂ may facilitate reducing the ripple on the signal V_{ERROR} and the resistor R_{Z} facilitates boosting the phase margin);

the amplifier 106 is likewise non mandatory, in so far as a source follower stage can be enough to perform a voltage-to-current conversion of the error signal V_{ERROR};

the output current mirrors facilitate magnifying the error current signal and also act as level shifters between different domains (if desired, for example from low-voltage to high-voltage rails);

the circuit is asymmetric, in so far as it is configured to sink an extra output current I_{EXTRA} and therefore it can only increase the DC-DC switching activity/frequency to counter an undesired drop below F_{MIN}: when the converter C is operating at an actual frequency F_{SW} higher than the frequency REF_{CLOCK} the proposed circuit saturates, accumulating a negative phase error; in that case V_{ERROR} and I_{EXTRA} become zero and no corrective action is implemented.

Operation of an inverting buck-boost DC-DC converter C regulating a voltage of −9V was simulated with the converter initially operating freely in deep PFM mode (very low operating frequency) at no load. The frequency limitation arrangement illustrated in FIG. 4 was then enabled (with F_{MIN} set to 400 kHz). After a transient, the arrangement illustrated in FIG. 4 had increased the converter operating frequency up to the desired limit. At 6.6 ms, a new load condition was applied and the arrangement illustrated in FIG. 4 reached a new steady state maintaining the DC-DC within the (lower) boundary of 400 kHz.

FIG. 7 illustrates a variant of the arrangement of FIG. 4 where the Miller effect is exploited in order to reduce the value of the “integrator” capacitor C₁, which facilitates reducing the semiconductor (silicon) area occupied by the circuit.

The designation Miller effect applies to an impedance (typically a capacitance) connected between the input and another node of an amplifier that can modify the amplifier input impedance, for instance by increasing the equivalent input capacitance of an (inverting) voltage amplifier due to amplification of the effect of capacitance between the amplifiers input and output terminals.

Parts or elements like parts or elements already discussed in connection with FIG. 1, FIG. 3 and FIG. 4 are indicated in FIG. 7 with the same reference symbols, without repeating for brevity a detailed description of these parts or elements.

Essentially, in the variant of FIG. 7 (to be considered essentially in comparison with FIG. 4), the error signal V_{ERROR} at the node E is again applied to one input of the differential amplifier 106 and also to filter circuitry coupled between the node E and ground GND and including (in the case of FIG. 7): the series connection of a (first) capacitor C₁ with a resistor R_{Z} coupled between the node E (output of the amplifier 106) and the (inverting) input of the amplifier 106; and a (second) capacitor C₂ coupled between the node E and ground GND.

The FLL-based solutions discussed in connection with FIGS. 2 to 7 share the same advantages of the PLL-based solution discussed in connection with FIG. 1; a possible difference lies in that in FIGS. 2 to 7 phase alignment of the signal REF_{CLOCK} and the signal HS_ON is no longer pursued, by paying attention to just the frequency limit instead. This may be advantageous in so far as loop compensation is simplified thus facilitating using a simpler type-I network.

To summarize, the solutions of FIG. 1 and FIG. 2 are exemplary of detection circuitry comprising:
a comparator PFD or FD having a first input 101 or 201 configured to have applied thereto the reference clock signal REF_{CLOCK} as well as a second input 102 or 202 configured to have applied thereto the pulsed drive signal HS_ON; and
charge pump circuitry 104, 105 coupled to the first input 101 or 201 and to the second input 102 or 202 of the comparator PFD or FD), the charge pump circuitry 104, 105 being configured to produce a voltage error signal V_{ERROR} in response to the switching frequency of the converter C falling below the lower bound F_{MIN} for the switching frequency F_{SW} of the converter C.

Further to summarize, the solutions of FIG. 1, FIG. 2, FIG. 4 and FIG. 7 are exemplary of detection circuitry comprising a comparator selected out of:
a phase-frequency detector (PFD, 101, 102, 103 in FIG. 1) having a first input 101 configured to have applied thereto the reference clock signal REF_{CLOCK} and a second input 102 configured to have applied thereto the pulsed drive signal HS_ON, with the phase-frequency detector configured—in conjunction with the charge pump 104, 105—to produce the error signal V_{ERROR} based on a phase difference between the reference clock signal REF_{CLOCK} and the pulsed drive signal HS_ON; or
a frequency detector (FD, 201, 202 in FIG. 2) having a first input 201 configured to have applied thereto the reference clock signal REF_{CLOCK} and a second input 202 configured to have applied thereto the pulsed drive signal HS_ON, with the frequency detector configured—again in conjunction with the charge pump 104, 105—to produce the error signal V_{ERROR} based on a frequency difference between the reference clock signal REF_{CLOCK} and the pulsed drive signal HS_ON;
a first frequency-to-voltage converter (301 in FIGS. 4 and 7) configured to have applied thereto the reference clock signal REF_{CLOCK} and to produce a first output voltage VF_{REF}, a second frequency-to-voltage converter (302 in FIGS. 4 and 7)) configured to have applied thereto the pulsed drive signal HS_ON and to produce a second output voltage VF_{HSON} plus a differential stage (303 in FIGS. 4 and 7) configured to produce—in conjunction with the filter composed by the capacitors C₁, C₂ and the resistor R_{Z}—the error signal V_{ERROR} based on the difference between the first output voltage VF_{REF} and the second output voltage VF_{HSON}.

As noted, a full first frequency-to-voltage converter such as the converter 301 in FIGS. 4 and 7 is not strictly mandatory and could be implemented as a “virtual” frequency-to-voltage converter including a simple equivalent voltage reference.

The solutions of FIG. 1, FIG. 2, FIG. 4 and FIG. 7 are exemplary of detection circuitry configured to produce a voltage error signal V_{ERROR} in response to the switching frequency of the converter C falling below the lower bound F_{MIN} set for the switching frequency F_{SW} of the converter C. In those solution the current sink circuitry comprises voltage-to-current conversion circuitry (see the integers 106, M_{P0}, M_{N0}, M_{P1}, M_{N1}, M_{N2}) configured to produce the “corrective” current I_{EXTRA} based on the voltage error signal V_{ERROR}.

As exemplified, the voltage-to-current conversion circuitry comprises: a voltage-to-current conversion stage (see, for instance, the elements indicated by the references 106, M_{P0}, M_{N0}, RB) configured to convert the voltage error signal V_{ERROR} into a current error signal I_{ERROR}; and current-mirror circuitry (such as the transistors M_{P1}, M_{N1}, M_{N2}) configured to mirror the current error signal I_{ERROR} into the corrective current I_{EXTRA}.

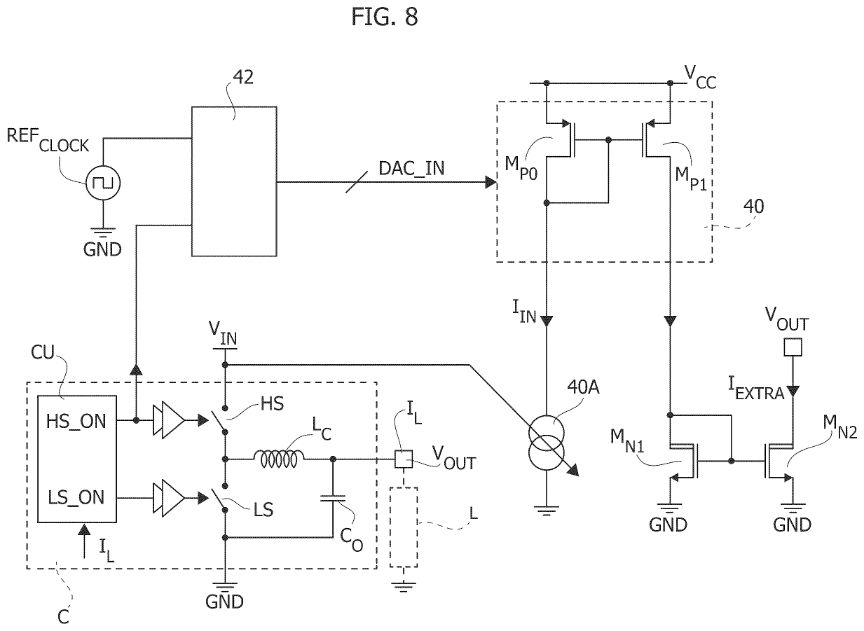

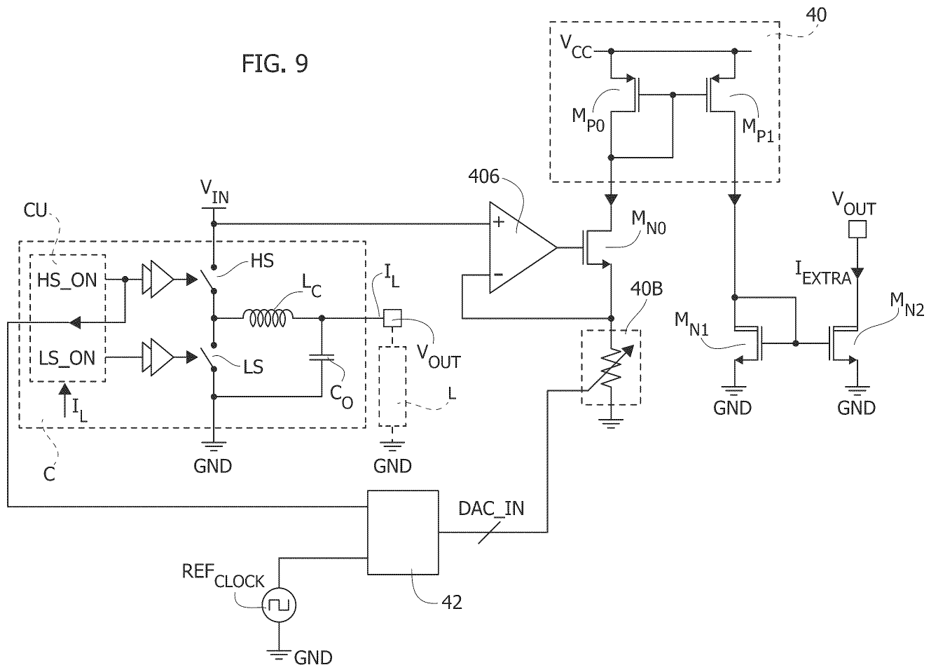

FIGS. 8 and 9 illustrate the possibility of implementing FLL-based operation as discussed previously by taking advantage of the inherent time-discrete nature of systems as considered herein by continuously monitoring the switching activity/frequency of the converter C (based on the driving signal HS_ON, for instance) and comparing it with an available time reference.

For the sake of brevity, parts or elements like parts or elements already discussed in connection with the previous figures are indicated in FIG. 8 and FIG. 9 with the same reference symbols. Therefore, a detailed description of these parts or elements that were already discussed will not be repeated.

For simplicity and ease of explanation, the reference clock REF_{CLOCK} has been assumed in the foregoing to express directly the lower frequency bound F_{MIN} under which converter operation is desired to be avoided.

In the solutions discussed in the following in connection with FIG. 8 and FIG. 9, the signal REF_{CLOCK} will be assumed to be just a generic clock signal that somehow conveys information as to the frequency F_{MIN}.

In fact, also the solutions discussed in connection with FIG. 8 and FIG. 9 involve performing a (here, discrete) comparison of REF_{CLOCK} and HS_ON (for instance) to detect if the converter C is operating below the specified limit F_{MIN}, with a variable and discrete extra current I_{EXTRA} sunk from the node V_{OUT} (via the output current mirror pair M_{N1}, M_{N2}). As in the solutions discussed in the foregoing, the extra current I_{EXTRA} adds to the load current I_{L} to implement a corrective action via a modulated dummy load obtained here with a simple current digital-to-analog converter (DAC) indicated with reference number 40.

The solutions discussed in connection with FIG. 8 and FIG. 9 include a digital core 42 that can be implemented as a finite-state-machine (FSM) or as a proportional-integral-derivative (PID) compensator.

The implementation based on FSM can be regarded as including two parts: detection plus adaptive corrective action.

To that effect the fixed clock signal REF_{CLOCK} can be assumed here to be a generic reference clock signal with a frequency that is (even much) higher than the “forbidden” frequency threshold F_{MIN}: the signal REF_{CLOCK} may be in the MHz range, for instance.

The signal REF_{CLOCK} is once more exploited as a time/frequency reference to be compared with the converter operating frequency of the converter C that is monitored (via HS_ON, for instance).

Comparing these signals facilitates understanding if the converter C is operating at a frequency that is not desired: specifically, if the converter is operating below a “lower bound” frequency limit F_{MIN}, a corrective action can be stimulated (CONDITION_UP, hereinafter).

This condition can be revealed by counting the rising-edges of the clock signal REF_{CLOCK} (as noted this is assumed here to be at an—even much—higher frequency than the “forbidden” frequency threshold F_{MIN}) between two consecutive rising edge of HS_ON, that is by counting the number of reference periods (number of CLOCK periods) in one switching cycle and noting that the following relation is satisfied:

$$[ {REF}_{CLOCK} / {F}_{MIN} ] - MARGIN\_UP \leq number of CLOCK periods .$$

Of course, this is just an exemplary option, in so far as the same result (obtaining information about the instantaneous operating frequency of the converter) can be obtained counting the falling edges in the place of the rising-edges.

The update rate of the corrective action and its amplitude step resolution (the resolution of the DAC 40) affect the bandwidth of the correction loop, so that a judicious trade-off between fast response and stability is involved.

The DAC resolution also affects system accuracy. The update rate of the corrective action can thus be divided by a factor N, to properly filter-out temporary converter transient conditions and limiting the loop bandwidth. The value N can be made selectable, starting from a default value N=4, for instance.

The same applies for a check related to the reduction of the corrective action.

For instance, if the converter C is operating above the minimum frequency limit F_{MIN}, counting the number of CLOCK periods of rising (or falling) edges of the reference clock signal between two consecutive edges of HS_ON (that is counting number of reference clock periods in one switching cycle) indicates that the following relation applies:

$$number of CLOCK periods \leq {REF}_{CLOCK} / {F}_{MIN} ] - MARGIN\_UP - MARGIN\_DN - 1$$

where MARGIN_UP and MARGIN_DN are two variables that can be exploited to introduce a desired hysteresis band ΔF_{HYST} wherein the corrective action is maintained (this can counter continuous undesired±1LSB variations of the DAC control word); the hysteresis value can be selected based on the DAC resolution.

Two finite state machines (FSMs) with four counters can be used to implement the digital core 42.

A first “short term” finite state machine (briefly “short” FSM or FSM_SHORT) can be used to evaluate the converter operating frequency (as expressed by HS_ON, for instance) by observing single (actual, instantaneous) switching cycles without any memory regarding what happened previously and provide immediate feedback signals PRE_ADD and PRE_REDUCE to a first counter 421 and a second counter 422 included along with a third counter 423 in the first “short” finite state machine.

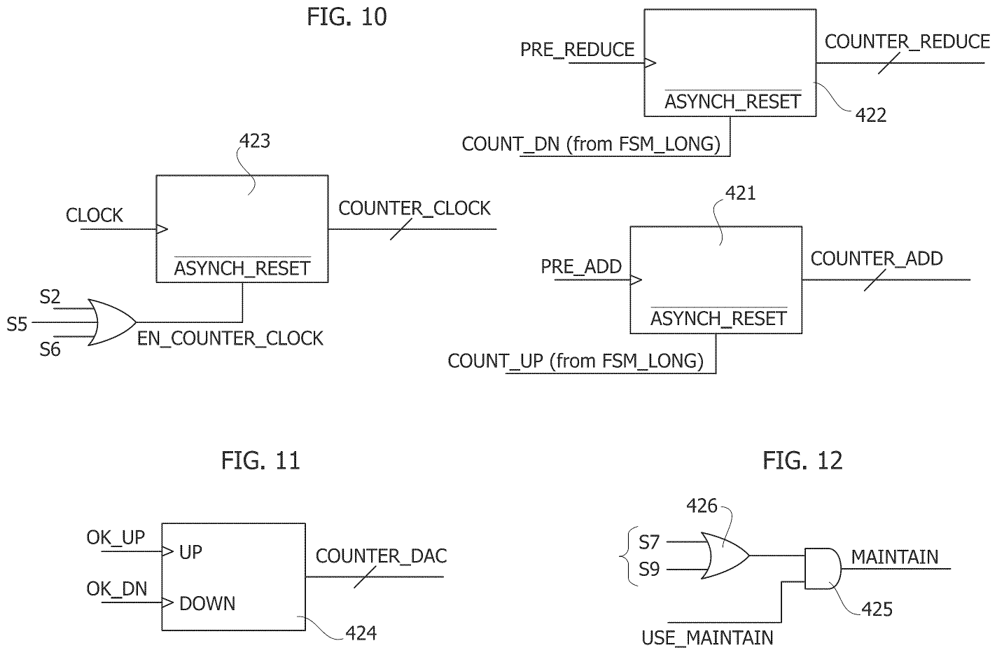

FIG. 10 reports for simplicity the counters and the combinatorial logic connected/coupled with the state-machine.

The counters 421 and 422 are reset at (negated) ASYNCH_RESET reset inputs by count signals COUNT_UP and COUNT_DN from the second “long term” finite state machine (briefly, “long” FSM or FSM_LONG) discussed in the following in connection with FIG. 11. The “long” FSM manages updating the corrective action considering N subsequent (consecutive) requests from the first, “short” FSM.

The counter 423 produces a COUNTER_CLOCK signal based on the reference clock signal (here simply CLOCK) and is reset at a (negated) ASYNCH_RESET reset input by a count enable signal EN_COUNTER_CLOCK.

The first (“short”) FSM can be configured to implement the following truth table, which reflects the operating frequency of the converter C: Table I-Truth table of the “short” FSM

| Converter operating | CONDI- | CONDI- | Outputs to |
|---|---|---|---|
| frequency | TION_UP | TION_DN | “long” FSM |
| Below the limit | ✓ | X | PRE_ADD = 1 |
| | | | PRE_REDUCE = 0 |
| Within hysteresis | X | X | PRE_ADD = 0 |
| band | | | PRE_REDUCE = 0 |
| Above the limit | X | ✓ | PRE_ADD = 0 |
| | | | PRE_REDUCE = 1 |

This FSM directly controls the three counters 421, 422, and 423 of FIG. 10 which keep track of different information: the counters 421 and 422 are used to count (at least) N requests (to reduce or increase the corrective action) from FSM_SHORT prior to update a current DAC command; such counters update (i.e., increase) their values at each rising-edge of the signal PRE_ADD (counter 421) and of the signal PRE_REDUCE (counter 422); and the counter 423 keeps track of how many clock periods are present between two consecutive rising (or falling) edges of HS_ON; reset of this counter (EN_COUNTER_CLOCK=0, since the reset is active low) is managed by the “short” FSM (based on states S2, S5 and S6 as discussed below) and basically involves a reset by the next edge of HS_ON or if CONDITION_UP is already satisfied before waiting the next edge on HS_ON (this can be implemented as the logic OR combination of different states of the “short” FSM).

The “short” FSM having connected/coupled therewith the counters and the combinatorial logic of FIG. 10 may be configured to provide the following outputs (a related graph is not reproduced for brevity):
PRE_ADD, set only in a state S8_PRE_ADD (0 otherwise);
PRE_REDUCE, set in two states S10_PRE_REDUCE and S8_PRE_REDUCE (0 otherwise);
S2, set only in a state S2_COUNT (0 otherwise);
S5, set only in a state S5_COUNT (0 otherwise);
S6, set only in a state S6_WAIT (0 otherwise).

As illustrated in FIG. 12, to the “long” FSM there is associated an “up/down counter DAC” 424 configured to receive therefrom OK_UP and OK_DN input commands and to produce an output signal COUNTER_DAC to be applied to the current DAC 42.

The “long” FSM can be configured to control directly the reset of the counters 421 and 422 if non-subsequent requests occur from the “short” FSM. In fact, in transient conditions, it may happen that the converter temporarily operates below the frequency limit, but then settles above that limit so that no corrective action is eventually required (the same for the opposite condition).

To that end, the “long” FSM facilitates detecting a consistent and real advantage resulting from performing a corrective action prior to any update of the current DAC control word, thus otherwise filtering out possible “spurious” requests from the “short” FSM. The “long” FSM provides therefore the following outputs (again, a related graph is not reproduced for brevity):
COUNT_UP, set only in states S1_COUNT_UP and S3_WAIT_CK0 (0 otherwise);
COUNT_DN, set only in states S2_COUNT_DN and S3_WAIT_CK0 (0 otherwise).

The “long” FSM evolves with inputs also provided by FSM_SHORT.

A dedicated combinatorial logic (not shown) checks if COUNTER_UP=N−1 or COUNTER_DN=N−1: setting OK_UP in the former case or OK_DN in the latter. Such events indicate that N subsequent and equal requests from the “short” FSM are received, this current DAC command is updated accordingly.

As illustrated in FIG. 11, signals OK_UP and OK_DN are used to respectively increase and decrease the dedicated up/down counter 424 (COUNTER_DAC), which directly controls the current DAC 42.

The signals OK_UP and OK_DN can also be used as inputs of the “long” FSM to acknowledge that a corrective action has been applied so that the “long” FSM can move back to the initial state and be prepared to check for a new corrective action: this process is carried out maintaining proper synchronization according to CLOCK signal.

In both the “short” and “long” FSMs a START signal is used as a sort of “enable” signal. CONDITION_UP and CONDITION_DN are set only when the aforementioned conditions are satisfied (0 otherwise).

These computations can be implemented with a combinatorial logic (not shown for simplicity).

Advantageously, as illustrated in FIG. 12 an additional feature—based on a signal designated MAINTAIN—can be embedded in both FSMs, with another possible reset mechanism provided to the counters 421 and 422 in FIG. 10. Such a feature facilitates accepting also N equal but non-subsequent commands from the “short” FSM, without resetting the counters 421, 422.

This means that: these counters are not reset by the “long” FSM until: 1) equal commands (PRE_ADD, PRE_REDUCE) are provided by the “short” FSM or 2) a switching cycle without any command (no command) from the “short” FSM occurs; and on the contrary, when an opposite command from the “short” FSM occurs, then the counter 421 or the counter 422 is reset.

As illustrated in FIG. 12, the signal MAINTAIN can be generated via an AND gate receiving as inputs i) a gating signal USE_MAINTAIN (indicating that such feature is enabled), and ii) the output from an OR gate that receives from the “short” FSM signals corresponding to the states S7 and S9 discussed previously.

If this feature is not used, as soon as no commands are provided from the “short” FSM during a switching cycle, the above counters are reset by the “long” FSM as discussed previously.

As discussed throughout this description, an adaptive corrective action countering undesired reduction of the switching frequency of the converter C below a “valley” frequency F_{MIN} is represented by an extra current I_{EXTRA} sunk from the output node at the regulated voltage V_{OUT}.

In solutions as illustrated in FIGS. 8 and 9 a current DAC 40 can be used driven by a “digital” core 42 (FSM-based as discussed previously, for instance).

In FIG. 8 a programmable current mirror 40 can be used including (not quite unlike the arrangements of FIGS. 1, 2, 4, and 7) a pair of gate-to-gate coupled MOSFET transistors M_{P0}, M_{P1}.

Of these MOSFET transistors: the first MOSFET transistor M_{P0} is a diode-coupled MOSFET arranged with the drain-source current flow path therethrough arranged in a current flow line between the voltage supply rail V_{CC} and ground GND to be traversed by a current I_{IN} which is a function of the input voltage V_{IN} to the converter C; the current seed 40A feeding the DAC 40 being made dependent on the input voltage V_{IN} to the converter C (which can be easily implemented in manner known to those of skill in the art) improves performance while minimizing DAC size; the second MOSFET transistors M_{P1} has the drain-source current flow path therethrough cascaded with drain-source current flow path through the first output MOSFET transistor M_{N1} in a current flow line between the voltage supply rail V_{CC} and ground GND configured to “mirror” the current I_{EXTRA} to be sunk from the output node V_{OUT}. The output current mirror magnifies the error current signal I_{EXTRA} and also facilitates voltage compliance with respect to the output regulated voltage (it can be high-voltage or HV).

Once more, the system is asymmetric, in so far as it is configured (only) to sink an extra output current, thus acting to increase the converter switching activity if below F_{MIN}. Again, when the converter is operating with at a switching frequency F_{SW} such that F_{SW}>F_{MIN}, the system saturates, accumulating a negative frequency error: I_{EXTRA} is zero (DAC_IN=0), and no corrective action takes place.

The DAC implementation of FIG. 8 is otherwise non mandatory: for example, a resistor-based DAC 40 can be used as illustrated in FIG. 9.

In that case, the output signal DAC_IN from the digital core 42 is used to vary the resistance of a programmable or “digital” resistor 40B included in a current flow line from the supply rail V_{CC} and ground GND, such a current flow line being through the cascaded arrangement of: the source-drain current flow path through the MOSFET transistor M_{P0}; the source-drain current flow path through a further MOSFET transistor M_{N0} (this is advantageously n-channel if M_{P0} is p-channel and the same symbol of FIGS. 1, 2, 4 and 7 is used for simplicity); and the variable resistor 40B.

A differential amplifier 406 drives the control terminal (gate, in the case of a field-effect transistor such as a MOSFET) of the MOSFET transistor M_{N0}, not quite unlike the amplifier 106 in FIGS. 1, 2, 4 and 7 with one input (non-inverting, for instance) thereof coupled to the input voltage V_{IN} to the converter C and the other input (inverting, for instance) coupled between the MOSFET transistor M_{N0} and the variable resistor 40B.

Here again, the amplifier 406 is not compulsory, in fact a source follower stage can be enough for V-to-I conversion of the voltage V_{IN} and render I_{EXTRA} dependent on V_{IN} (as noted, rendering the current seed feeding the DAC 40 dependent on the input voltage V_{IN} to the converter C improves performance while minimizing DAC size).

A mixed-signal system including FSMs plus a current DAC as described herein essentially behaves like an integrator.

The frequency detecting function is obtained with the “short” FSM coupled with a counter such as the counter 423, which provides a command related to the frequency error information.

To summarize, the FSM based solution just described implements detection circuitry that comprises counter circuitry configured to produce an error signal DAC_IN in response to the switching frequency F_{SW} of the converter C falling below the lower bound F_{MIN} by: producing a count (see the reference 423) of the number of edges of the reference clock signal REF_{CLOCK} occurring between subsequent edges of said pulsed drive signal HS_ON, with the reference clock signal REF_{CLOCK} having a frequency F_{CLOCK} (possibly much) higher than the lower bound F_{MIN} for the switching frequency of the converter (C), and detecting the count 423 being higher than an error threshold such as [F_{CLOCK}/F_{MIN}], possibly with a margin as represented by MARGIN_UP.

Such a frequency correcting arrangement was simulated in connection with an inverting buck-boost DC-DC converter regulating a voltage of −7V.

At the outset, the converter was operated in a deep PFM mode (with a very low operating frequency) at no load. The frequency limit feature was then enabled (with F_{MIN} set to 400 kHz) and after a transient the correction circuit increased the converter operating frequency up to the desired limit.

At 6.6 ms a new load condition was simulated and the system was found to faithfully reach a new steady state maintaining the DC-DC slightly above 400 kHz (427 kHz, exactly).

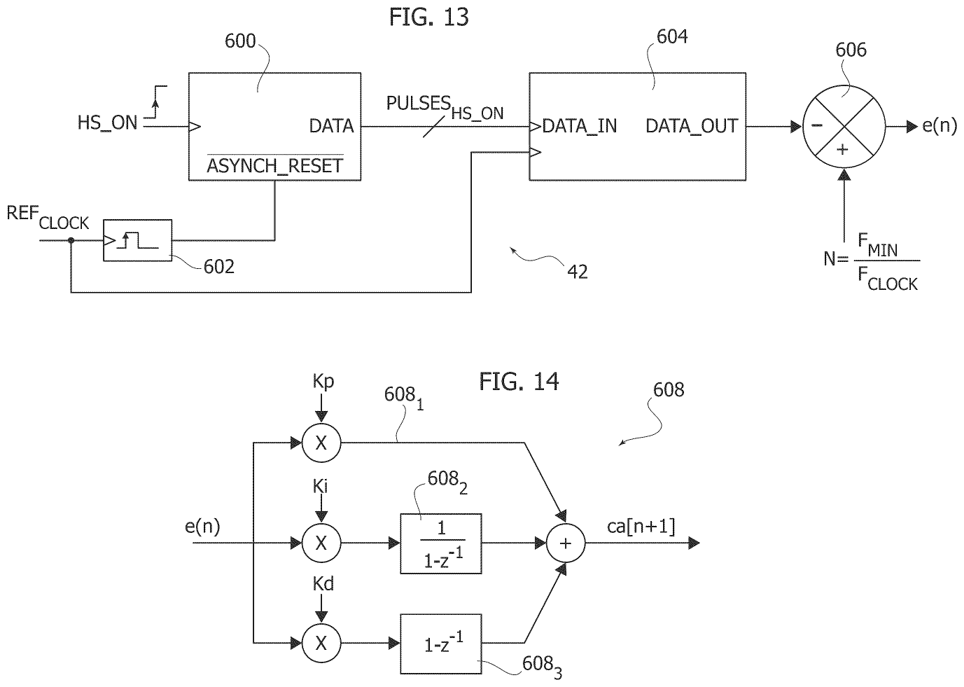

FIG. 13 is exemplary of the possibility of implementing the digital core 42 of FIG. 8 and FIG. 9 as a digital proportional-integral-derivative (PID) controller.

Also in this case, a fixed reference clock signal REF_{CLOCK} with a frequency F_{CLOCK}=F_{MIN}/N (this time smaller than F_{MIN}) is used as a time reference to define a sampling window.

Such a reference clock is used to define an update rate of the corrective action with period T_{CK}=N/F_{MIN} that is a period N time the period associated with the lower bound F_{MIN} for the switching frequency of the converter C.

Monitoring HS_ON (or any other signal indicative of the actual switching frequency of the converter C) and comparing its behavior with the reference clock facilitates obtaining a discrete quantized frequency error e[n] (essentially corresponding to V_{ERROR} as discussed previously).

For instance, such error e[n] can be obtained by counting the HS_ON pulses within a sampling window via a counter 600 clocked at each rising edge of the signal HS_ON and reset at an ASYNCH_RESET input with a signal derived from the reference clock signal REF_{CLOCK} via a pulse generator 602.

The pulse count on the signal HS_ON from the counter 600 is stored in a register 604 clocked by the reference clock signal REF_{CLOCK} and then applied to summing node 606 (with sign) wherein a value N=F_{MIN}/F_{CLOCK} is applied to the positive input of the summing node in order to obtain a subtraction with respect to N.

As depicted in FIG. 13, the counter 600 is reset at each pulse of the signal REF_{CLOCK} (rising or falling edge), and is increased at each HS_ON pulse (rising or falling edge). At each clock pulse the counter value PULSES_{HS_ON} is stored in the data register 604 and provided to a digital subtractor 606 to finally obtain the frequency error e[n].

The error e[n] can then be processed to yield a compensated error value ca[n+1] via a discrete PID compensator 608 as illustrated in FIG. 14.

As known to those of skill in the art, such a compensator 608 may comprise: a proportional path 6081, with gain Kp; an integral path 6082, with gain Ki; and a derivative path 6083, with gain Kd.

Providing a corrective action ca[n+1] resulting from the sum of the above paths.

Here again, the negative feedback correction path is closed by the DAC 40 (driven based on the signal e[n], possibly compensated as ca[n+1]) that converts the error e[n] into an extra current I_{EXTRA} that is sunk from the regulated output at the out node V_{OUT}.

To summarize, the PID based solution just described implements detection circuitry that comprises counter circuitry configured to produce an error signal DAC_IN in response to the switching frequency F_{SW} of the converter C falling below the lower bound F_{MIN} by: producing a count 600, 604 of the number of edges of the pulsed drive signal HS_ON occurring within a sampling window (as set by the block 602) given by the reference clock signal, wherein said reference clock signal REF_{CLOCK} has a frequency F_{CLOCK} that is 1/N times the lower bound F_{MIN} for the switching frequency of the converter, and detecting that the count is less than N (by subtracting N from the count at the node 606).

In both the FSM-based and the PID-based solutions just described in connection with FIGS. 8 to 14 the detection circuitry (see the digital core 42) is configured to produce a digital error signal e (n) in response to the switching frequency F_{SW} of the converter C falling below the lower bound F_{MIN} set for the switching frequency of the converter C.

The current sink circuitry comprises digital-to-analog conversion circuitry (40, 40A in FIG. 8 or 40, 406, 40B in FIG. 9) configured to produce the corrective current I_{EXTRA} based on a digital error signal. This can be possibly PID-compensated as ca[n+1] illustrated in FIG. 14.

Advantageously, the digital-to-analog conversion circuitry comprises a coupling node (see the references 40A in FIGS. 8 and 406 in FIG. 9) configured to receive the input signal V_{IN} to the converter C so that the digital-to-analog conversion circuitry produces the corrective current I_{EXTRA} based on the digital error signal e (n) also taking into account the input signal V_{IN} to the converter C.

The same general considerations and remarks apply to the present digital implementation and the various implementation options discussed previously.

The choice between analog and digital implementations may depend on the process technology available, the intended application and the desired performance level.

In general, a digital FLL-based implementation is advantageous in terms of versatility (multiple scenarios or application profiles) and may be less demanding in terms of quiescent current, in comparison with an analog FLL-based counterpart.

Mixed-signal FLL-based solutions (FIG. 8 and FIG. 9) can take advantage from a digital core embedded within a controller such as a DC-DC controller (HDL code written, synthetized and verified).

Without prejudice to the underlying principles, the details and embodiments may vary, even significantly, with respect to what has been described by way of example only, without departing from the extent of protection.

The extent of protection is determined by the annexed claims.

1. A correction circuit for a switching converter operating at a switching frequency that decreases in response to a decrease in a load current at an output node, comprising:
detection circuitry configured to receive a reference clock signal indicative of a lower bound for the switching frequency of the converter and a pulsed drive signal indicative of the switching frequency of the converter, the detection circuitry configured to produce an error signal in response to the switching frequency of the converter falling below said lower bound for the switching frequency of the converter; and
current sink circuitry driven by the detection circuitry, the current sink circuitry configured to be coupled to the output node of the converter, to receive the error signal from the detection circuitry and to sink from the output node of the converter a corrective current in response to the switching frequency of the converter falling below said lower bound for the switching frequency of the converter.

2. The circuit of claim 1, wherein the detection circuitry comprises:
a comparator having a first input configured to receive said reference clock signal and a second input configured to receive said pulsed drive signal; and
charge pump circuitry coupled to outputs of the comparator, the charge pump circuitry configured to produce a voltage as said error signal in response to the switching frequency of converter falling below said lower bound for the switching frequency of the converter.

3. The circuit of claim 1, wherein the detection circuitry comprises a comparator comprising a phase-frequency detector having a first input configured to receive said reference clock signal and a second input configured to receive said pulsed drive signal, the phase-frequency detector configured to produce said error signal based on a phase difference between said reference clock signal and said pulsed drive signal.

4. The circuit of claim 1, wherein the detection circuitry comprises a comparator comprising a frequency detector having a first input configured to receive said reference clock signal and a second input configured to receive said pulsed drive signal, the frequency detector configured to produce said error signal based on a frequency difference between said reference clock signal and said pulsed drive signal.

5. The circuit of claim 1, wherein the detection circuitry comprises a comparator comprising:
a first frequency-to-voltage converter configured to receive said reference clock signal and to produce a first output voltage;
a second frequency-to-voltage converter configured to receive said pulsed drive signal and to produce a second output voltage; and
a differential stage configured to produce said error signal based on the difference between the first output voltage and the second output voltage.

6. The circuit of claim 1, wherein the detection circuitry comprises counter circuitry configured to produce said error signal in response to the switching frequency of the converter falling below said lower bound for the switching frequency of the converter by producing a count of the number of edges of said reference clock signal occurring between subsequent edges of said pulsed drive signal, wherein said reference clock signal has a frequency higher than said lower bound for the switching frequency of the converter, and detecting the count being higher than an error threshold.

7. The circuit of claim 1, wherein the detection circuitry comprises counter circuitry configured to produce said error signal in response to the switching frequency of the converter falling below said lower bound for the switching frequency of the converter by producing a count of the number of edges of said pulsed drive signal occurring within a time frame between two pulses of said reference clock signal, wherein said reference clock signal has a frequency that is 1/N times said lower bound for the switching frequency of the converter, and detecting the count being lower than N.

8. The circuit of claim 1, wherein:
the detection circuitry is configured to produce a voltage error signal in response to the switching frequency of the converter falling below said lower bound for the switching frequency of the converter; and
the current sink circuitry comprises voltage-to-current conversion circuitry configured to produce said corrective current based on said voltage error signal.

9. The circuit of claim 8, wherein said voltage-to-current conversion circuitry comprises:
a voltage-to-current conversion stage configured to convert said voltage error signal into a current error signal; and
current-mirror circuitry configured to mirror the current error signal into said corrective current.

10. The circuit of claim 1, wherein:
the detection circuitry is configured to produce a digital error signal in response to the switching frequency of the converter falling below said lower bound for the switching frequency of the converter; and
the current sink circuitry comprises digital-to-analog conversion circuitry configured to produce said corrective current based on said digital error signal.

11. The circuit of claim 10, wherein the digital-to-analog conversion circuitry comprises a coupling node configured to receive an input signal to the converter wherein the digital-to-analog conversion circuitry is configured to produce said corrective current based on said digital error signal as a function of the input signal to the converter.

12. The circuit of claim 10, wherein the detection circuitry is configured to apply proportional-integral-derivative compensation to said digital error signal.

13. A converter device, comprising:
a switching converter configured to supply a load current to an electrical load coupled to an output node of the converter and to operate at a switching frequency that decreases in response to a decrease in said load current; and
the correction circuit according to claim 1;
wherein the detection circuitry of the correction circuit is coupled to the converter to receive therefrom said pulsed drive signal and to sink from the output node of the converter said corrective current in response to the switching frequency of the converter falling below said lower bound for the switching frequency of the converter.

14. A method, comprising:
supplying a load current to an electrical load coupled to an output node of a switching converter wherein the converter is operated at a switching frequency that decreases in response to a decrease in the load current supplied to the electrical load at said output node of the converter;
producing, based on a reference clock signal indicative of a lower bound for the switching frequency of the converter and a pulsed drive signal indicative of the switching frequency of the converter, an error signal indicating that the switching frequency of the converter falls below said lower bound for the switching frequency of the converter; and
sinking from the output node of the converter a corrective current in response to said error signal indicating that the switching frequency of the converter falls below said lower bound for the switching frequency of the converter.
